(19) United States
(12) Patent Application Publication
(10) Pub. No.: US 2017/0372972 A1
(43) Pub. Date: Dec. 28, 2017

(54) ELECTRONIC CIRCUIT DEVICE AND METHOD FOR MANUFACTURING ELECTRONIC CIRCUIT DEVICE

(71) Applicant: FUJIFILM CORPORATION, Tokyo (JP)

(72) Inventor: Yoshihisa USAMI, Kanagawa (JP)

(73) Assignee: FUJIFILM CORPORATION, Tokyo (JP)

(21) Appl. No.: 15/687,777

(22) Filed: Aug. 28, 2017

Related U.S. Application Data
(63) Continuation of application No. PCT/JP2016/053700, filed on Feb. 8, 2016.

(30) Foreign Application Priority Data
Mar. 26, 2015 (JP) 2015-064902

(51) Int. Cl. H01L 21/8234; H01L 27/092; H01L 23/522; H01L 29/786; H01L 21/8238

(52) U.S. Cl. CPC H01L 21/823475; H01L 27/0928; H01L 23/522; H01L 21/8238; H01L 29/786

(57) ABSTRACT

An electronic circuit device includes a plurality of logic circuit elements which output an output signal by performing a preset operation on an input signal. Transistors constituting the logic circuit elements each have a gate electrode provided on a substrate, an insulating layer electrically insulating the gate electrode, a source electrode, a drain electrode, and a semiconductor layer. Input signal wiring, to which the input signal is applied, is connected to the gate electrode and provided inside the insulating layer on the substrate. Output signal wiring, from which the output signal is taken out, is connected to the source electrode or the drain electrode and provided inside the insulating layer on the substrate. An electronic circuit performing a preset processing is constituted with the plurality of logic circuit elements.

### CROSS-REFERENCE TO RELATED APPLICATIONS

This application is a Continuation of PCT International Application No. PCT/JP2016/053700 filed on Feb. 8, 2016, which claims priority under 35 U.S.C. §119(a) to Japanese Patent Application No. 2015-064902 filed on Mar. 26, 2015. The above application is hereby expressly incorporated by reference, in its entirety, into the present application.

### BACKGROUND OF THE INVENTION

### 1. Field of the Invention

The present invention relates to an electronic circuit device having transistors including a semiconductor layer and to a method for manufacturing an electronic circuit device. Particularly, the present invention relates to an electronic circuit device, in which an electronic circuit can be constituted excluding logic circuits that do not normally operate even in a case where some of a plurality of logic circuits constituted with transistors including a semiconductor layer do not normally operate, and to a method for manufacturing an electronic circuit device.

### 2. Description of the Related Art

In an electronic circuit constituted with various logic circuits, in a case where some of the logic circuits do not normally operate, sometimes the whole electronic circuit do not function. In these cases, for transistors using a silicon semiconductor substrate, in order to make the electronic circuit normally operate, extra logic circuits are preliminarily formed at the time of design, the logic circuits in the portion that does not normally operate are not connected to each other and excluded, and the electronic circuit is constituted with the extra logic circuits. In recent years, in addition to the transistors using a silicon semiconductor substrate, transistors having a semiconductor layer in which the substrate is not a semiconductor have been suggested. Examples of such transistors include a transistor using an organic semiconductor layer constituted with an organic substance.

For example, the thin film electronic circuit device in JP2010-258334A includes a plurality of integrated circuit blocks which are constituted with thin film transistors using an organic semiconductor and matrix wiring which is for connecting the integrated circuit blocks to each other and crosses each other in the form of a network. For connecting the integrated circuit blocks to each other, a conductive material is selectively provided in each of the wiring-crossing portions of the matrix wiring by means of printing or the like on demand of a customer or a user at the site of use, whereby a circuit system is constituted. For the thin film transistors using an organic semiconductor, the circuit system is also constituted in a selective manner.

### SUMMARY OF THE INVENTION

In JP2010-258334A, although a plurality of integrated circuit blocks are connected to each other by means of adjusting wiring of the matrix wiring, the connection of the electronic circuit is not changed. Therefore, the technique in JP2010-258334A is not applicable to a case where some logic circuits of an electronic circuit do not normally operate and cannot be regarded as being highly versatile.

The present invention has been made to solve the problems of the technique of the related art described above, and an object thereof is to provide an electronic circuit device, in which an electronic circuit can be constituted excluding logic circuits that do not normally operate even in a case where some of a plurality of logic circuits constituted with transistors including a semiconductor layer do not normally operate, and a method for manufacturing an electronic circuit device.

In order to achieve the aforementioned object, a first aspect of the present invention provides an electronic circuit device comprising a plurality of logic circuit elements which are constituted with transistors and output an output signal by performing a preset operation on an input signal, in which the transistors each have a gate electrode provided on a substrate, an insulating layer electrically insulating the gate electrode, a source electrode, a drain electrode, and a semiconductor layer, input signal wiring, to which the input signal is applied, is connected to the gate electrode and provided inside the insulating layer on the substrate, output signal wiring, from which the output signal is taken out, is connected to the source electrode or the drain electrode and provided inside the insulating layer on the substrate, and an electronic circuit performing a preset processing is constituted with the plurality of logic circuit elements.

In order to connect the plurality of logic circuit elements to each other, it is preferable that at least one connection wiring connecting the input signal wiring of one logic circuit element to the output signal wiring of another logic circuit element, is provided on the insulating layer.

The connection wiring is preferably electrically connected to the input signal wiring and the output signal wiring through a conductive member formed in the insulating layer. The input signal wiring and the output signal wiring are preferably disposed in parallel to each other, and the connection wiring is disposed crossing the input signal wiring and the output signal wiring. The semiconductor layer is constituted with an organic semiconductor or an inorganic semiconductor, for example. Each of the transistors is preferably a combination of a P-type transistor and an N-type transistor. It is preferable that among the plurality of logic circuit elements, some logic circuit elements are selectively connected by using the connection wiring.

A second aspect of the present invention provides a method for manufacturing an electronic circuit device which includes a plurality of logic circuit elements constituted with transistors and outputting an output signal by performing a preset operation on an input signal and in which an electronic circuit performing a preset processing is constituted with the plurality of logic circuit elements, the transistors each have a gate electrode provided on a substrate, an insulating layer electrically insulating the gate electrode, a source electrode, a drain electrode, and a semiconductor layer, input signal wiring, to which the input signal is applied, is connected to the gate electrode and provided inside the insulating layer on the substrate, output signal wiring, from which the output signal is taken out, is connected to the source electrode or the drain electrode and provided inside the insulating layer on the substrate, and at least one connection wiring crossing the plurality of logic circuit elements is provided on the insulating layer such that the plurality of logic circuit elements are connected to each other, the method comprising a step of selecting the logic circuit elements to be connected from the plurality of logic circuit elements, a step of exposing the input signal wiring by forming a contact hole in the connection wiring and the insulating layer at an intersection point between the input signal wiring of the selected logic circuit elements and the connection wiring, a step of exposing the output signal wiring by forming a contact hole in the connection wiring and the insulating layer at an intersection point between the output signal wiring of the logic circuit elements and the connection wiring, and a step of electrically connecting the input signal wiring to the connection wiring and the output signal wiring to the connection wiring by filling each contact hole with a conductive member.

A third aspect of the present invention provides a method for manufacturing an electronic circuit device which includes a plurality of logic circuit elements constituted with transistors and outputting an output signal by performing a preset operation on an input signal and in which an electronic circuit performing a preset processing is constituted with the plurality of logic circuit elements, the transistors each have a gate electrode provided on a substrate, an insulating layer electrically insulating the gate electrode, a source electrode, a drain electrode, and a semiconductor layer, input signal wiring, to which the input signal is applied, is connected to the gate electrode and provided inside the insulating layer on the substrate, output signal wiring, from which the output signal is taken out, is connected to the source electrode or the drain electrode and provided inside the insulating layer on the substrate, the method comprising a step of selecting the logic circuit elements to be connected from the plurality of logic circuit elements, a step of exposing the output signal wiring by forming a contact hole in the insulating layer on the output signal wiring of the selected logic circuit elements, a step of exposing the input signal wiring by forming a contact hole in the insulating layer on the input signal wiring of the logic circuit elements into which the output signal of the selected logic circuit elements is input, and a step of forming the connection wiring electrically connecting the input signal wiring to the output signal wiring by filling each contact hole with a conductive member.

The input signal wiring and the output signal wiring are preferably disposed in parallel to each other, and the connection wiring is preferably disposed crossing the input signal wiring and the output signal wiring.

The step of selecting the logic circuit elements to be connected preferably includes a step of selecting logic circuit elements which can perform a preset operation by inspecting the plurality of logic circuit elements and selecting logic circuit elements which will constitute the electronic circuit from the selected logic circuit elements.

The semiconductor layer is constituted with an organic semiconductor or an inorganic semiconductor, for example. Each of the transistors is preferably a combination of a P-type transistor and an N-type transistor.

According to the electronic circuit device of the present invention and the method for manufacturing an electronic circuit device of the present invention, even in a case where some of a plurality of logic circuits constituted with transistors having a semiconductor layer do not normally operate, an electronic circuit can be constituted excluding the logic circuits that do not normally operate.

### BRIEF DESCRIPTION OF THE DRAWINGS

FIG. 1 is a schematic view showing an input processing device including an electronic circuit portion of an embodiment of the present invention.

FIG. 2 is a schematic view showing an example of a logic circuit constitution of an electronic circuit portion of an embodiment of the present invention.

FIG. 3 is a schematic view showing an example of a logic circuit of an electronic circuit portion of an embodiment of the present invention.

FIG. 4 is a schematic cross-sectional view showing an example of a thin film transistor constituting a logic circuit.

FIG. 5 is a schematic plan view specifically showing a logic circuit of an electronic circuit portion of an embodiment of the present invention.

FIG. 6 is a cross-sectional view of the logic circuit in FIG. 5 taken along the line M₁-M₂-M₃-M₄.

FIG. 7 is a schematic view for describing a method for connecting the logic circuits in an electronic circuit portion of an embodiment of the present invention.

FIG. 8 is a flowchart for describing a method for manufacturing an electronic circuit portion of an embodiment of the present invention.

FIG. 9 is a schematic view for describing a method for manufacturing an electronic circuit portion of an embodiment of the present invention.

FIG. 10 is a cross-sectional view taken along the line N-N in FIG. 9.

FIG. 11 is a cross-sectional view taken along the line Q-Q in FIG. 9.

FIG. 12 is a schematic cross-sectional view showing an electronic circuit portion prepared by a method for manufacturing an electronic circuit portion of an embodiment of the present invention.

FIG. 13 is a schematic view for describing a method for manufacturing an electronic circuit portion of an embodiment of the present invention.

FIG. 14 is a cross-sectional view taken along the line R-R in FIG. 13.

FIG. 15 is a schematic cross-sectional view showing another example of a method for manufacturing an electronic circuit portion of an embodiment of the present invention.

### DESCRIPTION OF THE PREFERRED EMBODIMENTS

Hereinafter, the electronic circuit device and the method for manufacturing an electronic circuit device of the present invention will be specifically described based on preferred embodiments illustrated in the attached drawings.

In the following description, “to” showing a range of numerical values includes the numerical values listed before and after “to”. For example, in a case where E is within a range of a numerical value α to a numerical value β, the range of E is a range including the numerical values α and β, which is represented by mathematical symbols α≦ε≦β.

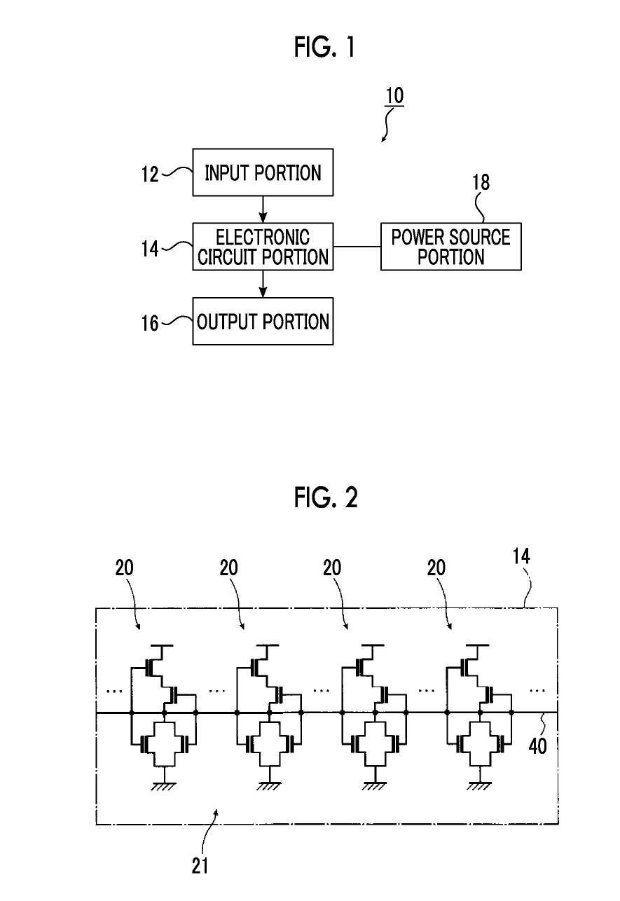

FIG. 1 is a schematic view showing an input processing device including an electronic circuit portion of an embodiment of the present invention. FIG. 2 is a schematic view showing an example of a logic circuit constitution of an electronic circuit portion of an embodiment of the present invention.

An input processing device 10 shown in FIG. 1 has an input portion 12, an electronic circuit portion 14, an output portion 16, and a power source portion 18. The electronic circuit portion 14 corresponds to the electronic circuit device of the present invention.

In the input processing device 10, input data is input as a data signal into the electronic circuit portion 14 from the input portion 12, data resulting from an operation is obtained by the execution of a preset processing in the electronic circuit portion 14 by the data signal which is the input data, and the data resulting from an operation is output to the output portion 16. The electronic circuit portion 14 is connected to the power source portion 18. From the power source portion 18, a preset voltage such as +Vcc is applied to logic circuit elements 20 of the electronic circuit portion 14, an operation is executed using the input data by the electronic circuit portion 14 constituted with a combination of logic circuit elements 20, and the data resulting from an operation is obtained.

The processing performed in the electronic circuit portion 14 of the input processing device 10 is not particularly limited, and include the four fundamental arithmetic operations. Furthermore, the processing performed in the electronic circuit portion 14 also includes, for example, arithmetic operations, integral calculus, differentiation, data signal amplification, and data signal attenuation.

The electronic circuit portion 14 shown in FIG. 2 includes a plurality of logic circuit elements 20 and is provided with, for example, one connection wiring 40 for connecting the plurality of logic circuit elements 20 to each other. Due to the connection wiring 40, the plurality of logic circuit elements 20 are connected to each other, and hence a single electronic circuit 21 is constituted with the plurality of logic circuit elements 20. In the electronic circuit 21, a preset processing is performed.

The constitution of the power source portion 18 is not particularly limited as long as a voltage of +Vcc can be applied to the logic circuit elements 20 of the electronic circuit portion 14, for example. As the power source portion 18, those generally used in electronic circuits can be appropriately used. The voltage application method is also appropriately selected according to the constitution of the electronic circuit portion 14. For the power source portion 18, a constitution in which voltage is applied to each of the logic circuit elements 20, a constitution in which voltage is applied to each of the groups consisting of the plurality of logic circuit elements 20, or a constitution in which voltage is applied to all of the logic circuit elements 20 at the same time may be adopted. For the power source portion 18, it is preferable to adopt a constitution in which voltage is not applied to logic circuit elements 20 that are decided not to be connected by an inspection which will be described later.

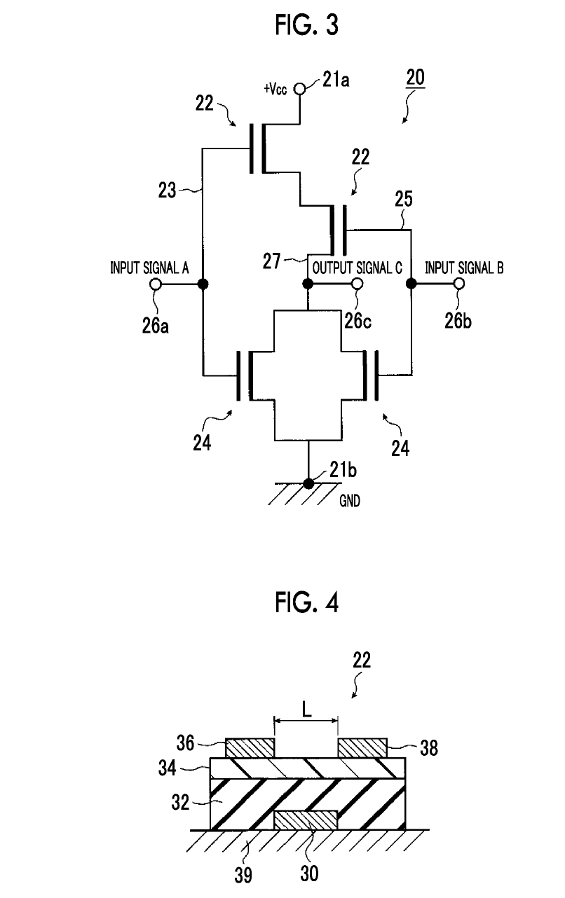

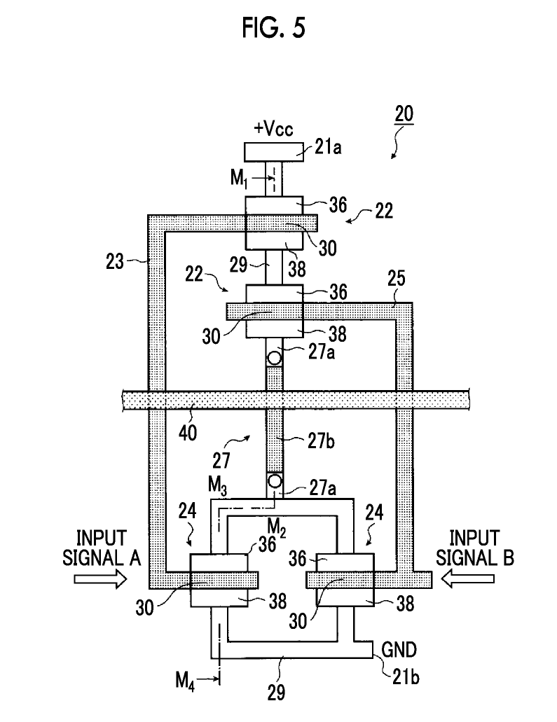

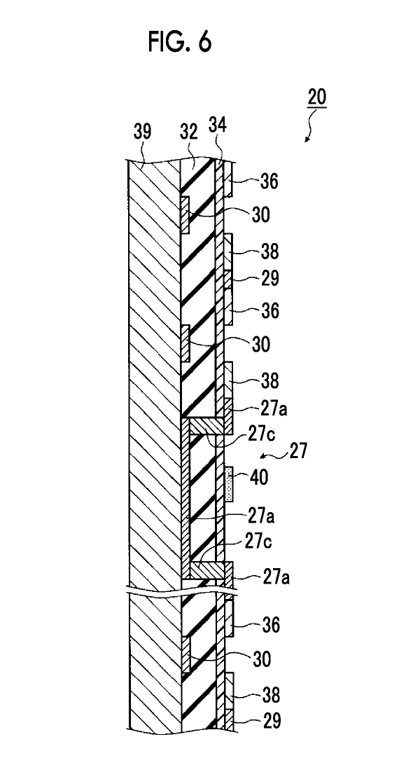

FIG. 3 is a schematic view showing an example of a logic circuit of an electronic circuit portion of an embodiment of the present invention. FIG. 4 is a schematic cross-sectional view showing an example of a thin film transistor constituting a logic circuit. FIG. 5 is a schematic plan view specifically showing a logic circuit of an electronic circuit portion of an embodiment of the present invention. FIG. 6 is a cross-sectional view of the logic circuit in FIG. 5 taken along the line M₁-M₂-M₃-M₄.

In FIGS. 5 and 6, the same constituents as the constituents of the P-type transistor 22 shown in FIGS. 3 and 4 are marked with the same references, and the details thereof will not be described.

The logic circuit elements 20 perform a preset operation for the input signal and output an output signal. As shown in FIGS. 3 and 5, the logic circuit elements 20 constitute a 2-input Negative-AND circuit (NAND circuit) for an input signal A and an input signal B.

The logic circuit elements 20 which can perform a preset operation are regarded as elements that normally operate, and the logic circuit elements 20 which cannot perform a preset operation are regarded as elements that do not normally operate. Whether or not the logic circuit elements 20 can perform an operation can be examined using an inspection device such as a tester.

In the logic circuit elements 20 shown in FIGS. 3 and 5, two P-type transistors 22 are connected to each other in series through wiring 29, and two N-type transistors 24 are connected to each other in parallel through output signal wiring 27 (hereinafter, referred to as output wiring 27). An output terminal 26c is provided in the output wiring 27, and an output signal C is taken outside from the output terminal 26c. For example, the output signal C is output to other logic circuits as the input signal A or the input signal B.

One P-type transistor 22 and one N-type transistor 24 are connected to each other through input signal wiring 23 (hereinafter, referred to as input wiring 23). The input wiring 23 is connected to a gate electrode 30 of the P-type transistor 22 and a gate electrode 30 of the N-type transistor 24. A first input terminal 26a is provided in the input wiring 23, and the input signal A is input through the first input terminal 26a.

One P-type transistor 22 and one N-type transistor 24 are connected to each other through input signal wiring 25 (hereinafter, referred to as input wiring 25). The input wiring 25 is connected to the gate electrode 30 of the P-type transistor 22 and the gate electrode 30 of the N-type transistor 24. A second input terminal 26b is provided in the input wiring 25, and the input signal B is input through the second input terminal 26b.

An input terminal 21a is provided at one end of the P-type transistor 22. The input terminal 21a is connected to the power source portion 18 (see FIG. 1) through wiring not shown in the drawing, and a voltage of +Vcc is applied thereto, for example. The input terminal 21a corresponds to the end portion of wiring 29 connected to drain electrodes 38 of two N-type transistors 24 shown in FIG. 5.

In two N-type transistors 24, the side not being connected to the P-type transistor 22 is provided with a ground terminal 21b which is grounded.

Although the P-type transistor 22 and the N-type transistor 24 are different from each other in the respect that whether a semiconductor layer 34 (see FIG. 4) is a P-type or an N-type, the transistors have the same element structure which is called a bottom gate-type top contact structure. Accordingly, herein, the P-type transistor 22 will be described for example, and the N-type transistor 24 will not be described. The semiconductor layer 34 is constituted with an organic semiconductor, for example.

As shown in FIG. 4, in the P-type transistor 22, the gate electrode 30 is formed on a substrate 39. On the substrate 39, an insulating layer 32 covering the gate electrode 30 is formed. The insulating layer 32 is generally called a gate insulating layer. The insulating layer 32 functions as an insulating layer of the input wiring 23 and the input wiring 25 as will be described later, and also functions to insulate the gate electrode 30 as described above.

The semiconductor layer 34 is formed on the insulating layer 32. On the semiconductor layer 34, a source electrode 36 and the drain electrode 38 are formed separating from each other by the area of the gate electrode 30.

The semiconductor layer 34 is a P-type in the P-type transistor 22 and an N-type in the N-type transistor 24.

The materials of the substrate 39, the gate electrode 30, the insulating layer 32, the semiconductor layer 34, the source electrode 36, and the drain electrode 38 of the P-type transistor 22 and the N-type transistor 24 will be specifically described later.

The P-type transistor 22 and the N-type transistor 24 have a structure called bottom gate-type top contact, but are not limited to the structure. As long as the relationship among the input wiring 23, the output wiring 27, the input wiring 25, and the connection wiring 40 which will be described later can be maintained, transistors having other structures can be appropriately used. In a case where a transistor having a bottom gate-type structure is used, it is easy to maintain the relationship among the input wiring 23, the output wiring 27, the input wiring 25, and the connection wiring 40. Furthermore, the P-type transistor 22 and the N-type transistor 24 can be combined to establish a complementary metal oxide semiconductor (CMOS) structure.

As shown in FIGS. 2 and 5, the connection wiring 40 extending in one direction is provided across the input wiring 23, the output wiring 27, and the input wiring 25. The input wiring 23, the output wiring 27, and the input wiring 25 are disposed in parallel to each other. The connection wiring 40 is disposed in a direction orthogonal to a direction along which the input wiring 23, the output wiring 27, and the input wiring 25 extend, and each connection wiring 40 extends in the same direction. That is, the connection wiring 40 is disposed orthogonal to the input wiring 23, the output wiring 27, and the input wiring 25. The plurality of logic circuit elements 20 can be connected to each other through the connection wiring 40. The direction of the connection wiring 40 is not limited to the orthogonal direction, and the connection wiring 40 may be disposed crossing the input wiring 23, the output wiring 27, and the input wiring 25.

As described above, the input wiring 23 is connected to the gate electrode 30 of the P-type transistor 22 and the gate electrode 30 of the N-type transistor 24, and is disposed inside the insulating layer 32 on the substrate 39. Furthermore, as described above, the input wiring 25 is connected to the gate electrode 30 of the P-type transistor 22 and the gate electrode 30 of the N-type transistor 24, and is disposed inside the insulating layer 32 on the substrate 39.

The output wiring 27 connects the drain electrode 38 of the P-type transistor 22 to the source electrode 36 of the N-type transistor 24, and is disposed on the semiconductor layer 34. As shown in FIG. 6, the connection wiring 40 is disposed on the semiconductor layer 34. Accordingly, the connection wiring 40 interferes with the output wiring 27. Therefore, as shown in FIG. 6, the output wiring 27 is divided into a wiring portion 27a disposed on the semiconductor layer 34 and a wiring portion 27b disposed inside the insulating layer 32 on the substrate 39, and has a constitution in which the wiring portion 27a and the wiring portion 27b are connected to each other through a via 27c. In a case where this constitution is adopted, the input wiring 23, a portion of the output wiring 27, and the input wiring 25 are disposed inside the insulating layer 32 on the substrate 39, and the connection wiring 40 can be disposed on the same surface on which the source electrode 36 and the drain electrode 38 are formed, that is, on the semiconductor layer 34 without interfering the output wiring 27. The via 27c is a cylindrical conductive member constituted with a conductive material. From the viewpoint of the characteristics such as bonding properties and electric resistance, it is preferable that the wiring portion 27a, the wiring portion 27b, and the via 27c are constituted with the same material.

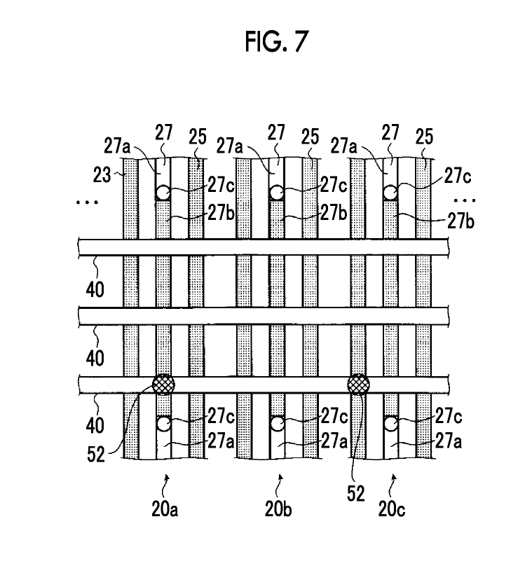

In FIGS. 2, 5, and 6, only one connection wiring 40 is illustrated. However, a plurality of connection wiring 40 may be provided, and as shown in FIG. 7, a constitution may be adopted in which three connection wiring 40 are provided. In FIG. 7, only the input wiring 23, the output wiring 27, the input wiring 25, and a plurality of connection wiring 40 are shown while other constituents are not illustrated.

In a case where logic circuit elements 20b among logic circuit elements 20a, logic circuit elements 20b, and logic circuit elements 20c shown in FIG. 7 are found not to normally operate through inspection using an inspection device such as a tester, the logic circuit elements 20b are not connected and excluded. In this case, the logic circuit elements 20a and the logic circuit elements 20c that normally operate are selectively connected to each other by using at least one connection wiring 40. The connection wiring 40 is electrically connected to the wiring portion 27b of the output wiring 27 of the logic circuit elements 20a through the via 52 which will be specifically described later. The via 52 is constituted with a conductive material, passes through the connection wiring 40 and the insulating layer 32, and reaches the wiring portion 27b.

Furthermore, the connection wiring 40 is electrically connected to the input wiring 23 of the logic circuit elements 20c through the via 52 which will be specifically described later. The via 52 is a cylindrical conductive member constituted with a conductive material such as a metal, passes through the connection wiring 40 and the insulating layer 32, and reaches the input wiring 23.

As described so far, even in a case where the semiconductor layer 34 is used, it is possible to obtain the electronic circuit 21 (see FIG. 2) in which a preset processing is performed in the electronic circuit portion 14 (see FIG. 1).

The logic circuit elements 20a, the logic circuit elements 20b, and the logic circuit elements 20c have the same constitution as the aforementioned logic circuit elements 20. Therefore, details of the logic circuit elements 20a to 20c will not be described. All of the logic circuit elements 20 and 20a to 20c constitute a 2-input Negative-AND circuit (NAND circuit), but they are not limited thereto. For example, the logic circuit elements may constitute an AND circuit, an OR circuit, a Negative OR circuit (NOR circuit), an Exclusive OR circuit (XOR circuit), and a negative logic circuit (NOT circuit). In the electronic circuit portion 14, various logic circuits described above including the Negative-AND circuit (NAND circuit) may be constituted with two or more logic circuit elements or two or more kinds of logic circuit elements. The electronic circuit portion 14 is appropriately provided with as many logic circuit elements as necessary that are of a kind required for constituting an electronic circuit necessary for operation.

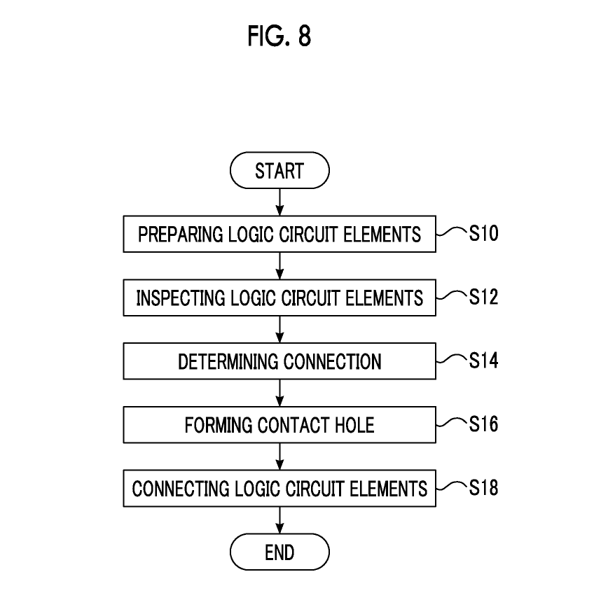

Next, a method for manufacturing the electronic circuit portion 14 will be described using FIGS. 8 to 12.

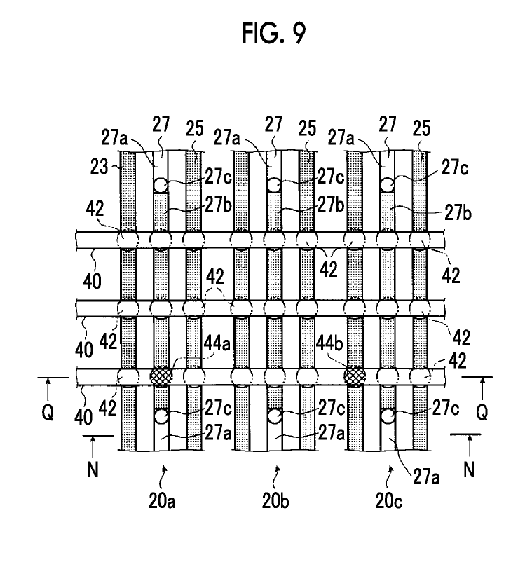

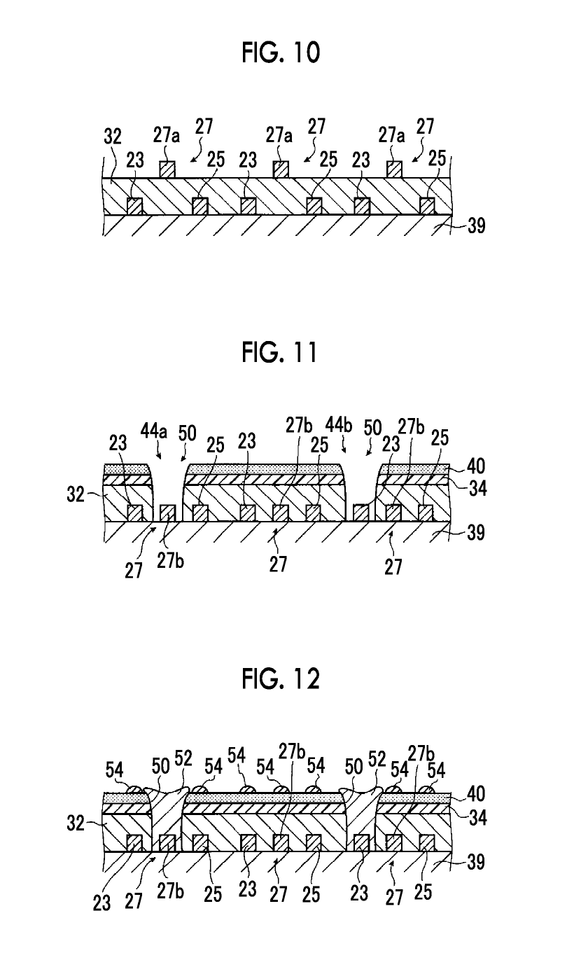

FIG. 8 is a flowchart for describing a method for manufacturing an electronic circuit portion of an embodiment of the present invention. FIG. 9 is a schematic view for describing a method for manufacturing an electronic circuit portion of an embodiment of the present invention. FIG. 10 is a cross-sectional view taken along the line N-N in FIG. 9. FIG. 11 is a cross-sectional view taken along the line Q-Q in FIG. 9. FIG. 12 is a schematic cross-sectional view showing an electronic circuit portion prepared by a method for manufacturing an electronic circuit portion of an embodiment of the present invention.

As shown in FIG. 8, first, in order to obtain the electronic circuit 21 (see FIG. 2) used for the operation and processing performed in the electronic circuit portion 14 (see FIG. 1), a plurality of logic circuit elements are formed and prepared (Step S10).

Then, the plurality of logic circuit elements are inspected using an inspection device such as a tester (Step S12). As the inspection, a dummy signal is input as an input signal into each of the logic circuit elements, an output signal is obtained through an operation, and the output signal is measured. Furthermore, whether the output is appropriate as an operation result based on the logic circuit elements with respect to the input of the dummy signal is determined. From the plurality of logic circuit elements, logic circuit elements that normally operate are selected.

Thereafter, according to the constitution of the electronic circuit portion 14, the logic circuit elements determined not to normally operate in Step S12 are excluded, and from the logic circuit elements that normally operate, the combination of the logic circuit elements which will constitute the electronic circuit 21 (see FIG. 2) is determined (Step S14).

Subsequently, based on the combination of the logic circuit elements determined in Step S14, the logic circuit elements are connected to each other. In this case, for example, a contact hole is formed which reaches the input wiring 23 and 25 of the logic circuit elements connected or reaches the wiring portion 27b of the output wiring 27 (Step S16), and the contact hole is filled with a conductive material so as to form a via, thereby connecting the logic circuit elements to each other (Step S18). By connecting the logic circuit elements to each other in this way, the electronic circuit 21 (see FIG. 2) can be constituted, and the electronic circuit portion 14 (see FIG. 2) can be obtained.

Next, the connection of the logic circuit elements to each other will be more specifically described.

For example, a case will be described in which the logic circuit elements 20b among the logic circuit elements 20a, the logic circuit elements 20b, and the logic circuit elements 20c shown in FIG. 9 do not normally operate, and hence the logic circuit elements 20a and the logic circuit elements 20c are connected to each other.

In the logic circuit elements 20a, the logic circuit elements 20b, and the logic circuit elements 20c shown in FIG. 9, within the region in which the connection wiring 40 is not provided, the input wiring 23 and the input wiring 25 are disposed inside the insulating layer 32 on the substrate 39 as shown in FIG. 10, and the wiring portion 27a of the output wiring 27 is disposed on the semiconductor layer 34.

In order for the output signal C of the logic circuit elements 20a shown in FIG. 9 to be input as the input signal A into the logic circuit elements 20c, the wiring portion 27b of the output wiring 27 of the logic circuit elements 20a is connected to the input wiring 23 of the logic circuit elements 20c by using the connection wiring 40.

In this case, first, at an intersection point 44a between the input wiring 23 of the logic circuit elements 20a shown in FIG. 9 and the connection wiring 40, a contact hole 50 is formed as shown in FIG. 11 such that the wiring portion 27b of the output wiring 27 is exposed.

At an intersection point 44b between the input wiring 23 of the logic circuit elements 20c shown in FIG. 9 and the connection wiring 40, the contact hole 50 is formed as shown in FIG. 11 such that the input wiring 23 is exposed.

Then, in order to fill the two contact holes 50, for example, a metal is vapor-deposited thereonto by a vapor deposition method by using a mask (not shown in the drawing), thereby forming the via 52 shown in FIG. 12 in the contact hole 50.

As the mask, for example, it is possible to use a metal plate in which openings are formed in a region corresponding to intersection points 42 between the input wiring 23, the output wiring 27 as well as the input wiring 25 and the plurality of connection wiring 40. From the viewpoint of binding properties and the like, the vapor-deposited metal is preferably the same material as the connection wiring 40.

Because the mask having the aforementioned constitution is used, a metal layer 54 is formed in a region corresponding to the intersection point 42 on the connection wiring 40 other than the contact hole 50. It is preferable to form the metal layer 54 in the region corresponding to the intersection point 42 on the connection wiring 40 by using the aforementioned mask, because then a via can be formed in each contact hole by a single vapor deposition even at a site where many members are connected to each other.

The method for forming the via 52 is not limited to the vapor deposition method using a mask, and the via 52 may be formed only at the intersection points 44a and 44b by using an ink jet method or the like.

The contact hole 50 is formed by evaporating or melting the connection wiring 40 and the insulating layer 32 by using laser beams, for example. The wavelength of the laser beams is appropriately set according to the material, the thickness, and the like of the connection wiring 40 and the insulating layer 32, and is not particularly limited. The wavelength of the laser beams is 0.1 to 12 μm for example, preferably 0.2 to 2 μm, more preferably 0.24 to 1.1 μm, and most preferably 1,064 nm, a half of 1,064 nm, a third of 1,064 nm, or a fourth of 1,064 nm. The method for forming the contact hole 50 is not limited to the method using laser beams. However, it is preferable to use laser beams, because then the positioning of the laser beam irradiation device is easy even in a case where known techniques are used, and the contact hole 50 can be formed in a narrow region by reducing the beam size of the laser beams. Furthermore, the influence of heat exerted on a region other than the contact hole 50 can be reduced.

By adopting the constitution in which the input wiring 23 and 25 and the output wiring 27 can be electrically connected using the connection wiring 40 on the semiconductor layer 34, in a case where the plurality of logic circuit elements 20 are connected to each other so as to obtain the electronic circuit 21 (see FIG. 2) performing a preset operation or processing, the only thing has to be done is to form the contact hole 50 exposing the wiring and to provide the via 52 electrically connecting the connection wiring 40 and the wiring in the contact hole 50. Accordingly, it is possible to easily obtain the electronic circuit 21 (see FIG. 2) with avoiding the logic circuit elements 20b that do not normally operate.

The method for connecting the logic circuit elements to each other is not limited to the aforementioned connection method. Other methods for manufacturing the electronic circuit portion 14 will be described using FIGS. 8 and 13 to 15.

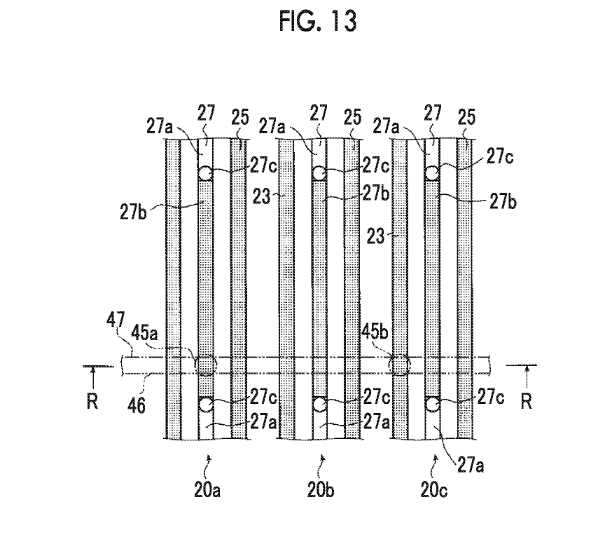

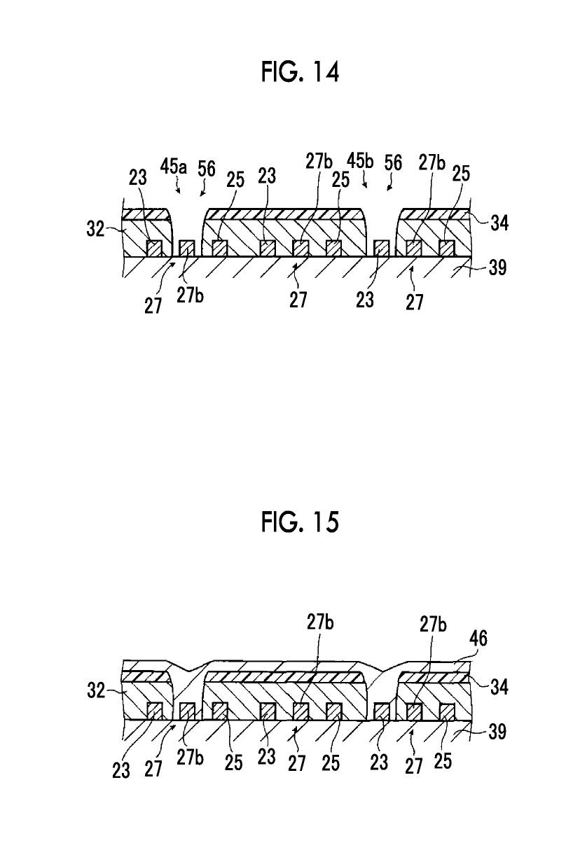

FIG. 13 is a schematic view for describing a method for manufacturing an electronic circuit portion of an embodiment of the present invention. FIG. 14 is a cross-sectional view taken along the line R-R in FIG. 13. FIG. 15 is a schematic cross-sectional view showing another example of the method for manufacturing an electronic circuit portion of an embodiment of the present invention.

In FIGS. 13 to 15, the same constituents as in FIGS. 9 to 12 are marked with the same references, and details thereof will not be described. Furthermore, details of the overlapping steps will not be described.

The logic circuit elements 20a, the logic circuit elements 20b, and the logic circuit elements 20c shown in FIG. 13 will be described, for example. As shown in FIG. 14, the input wiring 23, the wiring portion 27b, and the input wiring 25 are disposed inside the insulating layer 32 on the substrate 39.

First, the connection wiring 40 is not formed on the logic circuit elements 20a, the logic circuit elements 20b, and the logic circuit elements 20c. A plurality of logic circuit elements having such a constitution are prepared (Step S10).

Then, the logic circuit elements 20a, the logic circuit elements 20b, and the logic circuit elements 20c are inspected using an inspection device such as a tester (Step S12), and logic circuit elements that normally operate are selected. At this stage, the logic circuit elements that do not normally operate are excluded from the logic circuit elements that will constitute an electronic circuit and regarded as elements not being connected.

In Step S12, from the logic circuit elements 20a, the logic circuit elements 20b, and the logic circuit elements 20c, the logic circuit elements 20b are selected as elements that do not normally operate.

Then, the combination of the logic circuit elements is determined (Step S14). In this case, the logic circuit elements 20a and the logic circuit elements 20c are connected to each other.

Next, the connection of the logic circuit elements 20a to the logic circuit elements 20c will be more specifically described. In order for the output signal C of the logic circuit elements 20a shown in FIG. 13 to be input as the input signal A into the logic circuit elements 20c, the wiring portion 27b of the output wiring 27 of the logic circuit elements 20a is electrically connected to the input wiring 23 of the logic circuit elements 20c by forming connection wiring 46 orthogonal to the input wiring 23, the output wiring 27, and the input wiring 25.

In this case, first, at an intersection point 45a between the input wiring 23 of the logic circuit elements 20a shown in FIG. 13 and a region 47 in which the connection wiring 46 is supposed to be formed, a contact hole 56 is formed as shown in FIG. 14 (Step S16) such that the wiring portion 27b of the output wiring 27 is exposed. The contact hole 56 is formed using laser beams, for example. Because the wavelength of the laser beams forming the contact hole 56 is the same as the wavelength of the laser beams forming the aforementioned contact hole 50, details thereof will not be described.

At an intersection point 45b between the input wiring 23 of the logic circuit elements 20c shown in FIG. 13 and the region 47 in which the connection wiring 46 is supposed to be formed, the contact hole 56 is formed as shown in FIG. 14 (Step S16) such that the input wiring 23 is exposed. The region 47 in which the connection wiring 46 is supposed to be formed is a region extending in a direction orthogonal to the input wiring 23, the output wiring 27, and the input wiring 25.

Then, in order to fill the two contact holes 56 and to electrically connect the wiring portion 27b of the logic circuit elements 20a to the input wiring 23 of the logic circuit elements 20c, for example, a metal is vapor-deposited thereonto by a vapor deposition method by using a mask (not shown in the drawing), thereby filling the contact holes 56 with a metal and forming the connection wiring 46 shown in FIG. 15 (Step S18). As the mask, for example, it is possible to use a metal plate in which openings corresponding to the region 47, in which the connection wiring 46 is supposed to be formed, are formed.

By using the mask having the aforementioned constitution, the connection wiring 46 is formed which electrically connects the wiring portion 27b of the logic circuit elements 20a to the input wiring 23 of the logic circuit elements 20c. The method for forming the connection wiring 46 is not limited to the vapor deposition method using a mask, and the connection wiring 46 may be formed using an ink jet method, a printing method, and the like.

In this case, by adopting the constitution in which the input wiring 23 and 25 and the output wiring 27 can be electrically connected by using the connection wiring 46 on the semiconductor layer 34, in a case where the plurality of logic circuit elements 20 are connected to each other so as to obtain the electronic circuit 21 (see FIG. 2) performing a preset operation, the only thing has to be done is to form the contact hole 56 exposing the wiring and to form the connection wiring 46 electrically connecting wiring to each other in the contact hole 56. Accordingly, it is possible to form the connection wiring 46 and to electrically connect the normally operating logic circuit elements 20a to the logic circuit elements 20b with avoiding the logic circuit elements 20b that do not normally operate. Consequently, the electronic circuit 21 (see FIG. 2) can be easily obtained.

Next, the materials of the substrate 39, the gate electrode 30, the insulating layer 32, the semiconductor layer 34, the source electrode 36, and the drain electrode 38 relating to the P-type transistor 22 and the N-type transistor 24 will be described.

The substrate 39 has insulating properties and supports the gate electrode 30 and the insulating layer 32.

The material, the shape, the size, the structure, and the like of the substrate 39 are not particularly limited. The substrate 39 can be appropriately selected according to the purpose as long as it has predetermined insulating properties.

As the substrate, it is possible to use substrates formed of materials such as an inorganic material including glass, Yttria-Stabilized Zirconia (YSZ), a resin, a resin composite material, and the like.

Particularly, the substrates constituted with a resin or a resin composite material are preferable because they are lightweight and flexible and have light-transmitting properties.

Specifically, it is possible to use a substrate formed of a synthetic resin such as polybutylene terephthalate, polyethylene terephthalate, polyethylene naphthalate, polybutylene naphthalate, polystyrene, polycarbonate, polysulfone, polyethersulfone, polyarylate, allyl diglycol carbonate, polyamide, polyimide, polyamide imide, polyether imide, polybenzazole, polyphenylene sulfide, polycycloolefin, a norbornene resin, a fluororesin such as polychlorotrifluoroethylene, a liquid crystal polymer, an acryl resin, an epoxy resin, a silicone resin, an ionomer resin, a cyanate resin, a cross-linked fumaric acid diester, a cyclic polyolefin, an aromatic ether, a maleimide olefin, cellulose, or an episulfide compound, a substrate formed of a composite plastic material of the aforementioned synthetic resin and silicon oxide particles, a substrate formed of a composite plastic material of the aforementioned synthetic resin and metal nanoparticles, inorganic oxide nanoparticles, or inorganic nitride nanoparticles, a substrate formed of a composite plastic material of the aforementioned synthetic resin and carbon fiber or carbon nanotubes, a substrate formed of a composite plastic material of the aforementioned synthetic resin and glass flake, glass fiber, or glass beads, a substrate formed of a composite plastic material of the aforementioned synthetic resin and clay mineral or particles having a crystal structure derived from mica, a laminated plastic substrate having at least one bonding interface between thin glass and any of the aforementioned synthetic resins, a substrate formed of a composite material having barrier properties including at least one or more bonding interfaces by adopting a constitution in which an inorganic layer and an organic layer (the aforementioned synthetic resin) are alternately laminated, a stainless steel substrate, a multilayered metal substrate in which stainless steel and different metals are laminated, an aluminum substrate, or an aluminum substrate with an oxide film whose surface is subjected to an oxidation treatment (for example, an anodization treatment) to improve the insulating properties of the surface, and the like.

As the resin substrate, the substrates which are excellent in heat resistance, dimensional stability, solvent resistance, electrical insulating properties, and workability and have low gas permeability and low hygroscopicity are preferable. The resin substrate may include a gas barrier layer for preventing permeation of moisture and oxygen, an undercoat layer for improving the flatness of the resin substrate or the adhesiveness with respect to the lower electrode, and the like.

The thickness of the substrate 39 is preferably equal to or greater than 50 μm and equal to or less than 500 μm. In a case where the thickness of the substrate 39 is equal to or greater than 50 μm, the flatness of the substrate 39 is improved. In a case where the thickness of the substrate 39 is equal to or less than 500 μm, the flexibility of the substrate is improved, and hence it becomes easier to use the substrate as a substrate for a flexible device. The thickness at which the substrate exhibits sufficient flatness and flexibility varies with the material constituting the substrate 39, and accordingly, the thickness needs to be set according to the material of the substrate. However, generally, the thickness is within a range of equal to or greater than 50 μm and equal to or less than 500 μm.

A channel length L (see FIG. 4) which is a distance between the source electrode 36 and the drain electrode 38 is preferably 0.1 μm to 10,000 μm, more preferably 1 μm to 1,000 μm, and particularly preferably 10 μm to 500 μm.

In a case where the channel length L (see FIG. 4) is small, contact resistance exerts a big influence, or the mobility of the transistor as a transistor element deteriorates. Therefore, high accuracy is required at the time of preparing the transistor, and hence the productivity is reduced. Accordingly, from the viewpoint of preventing the mobility deterioration and productivity, the channel length L (see FIG. 4) is preferably equal to or greater than 0.1 μm.

In a case where the channel length L (see FIG. 4) is large, the electric current between the source electrode 36 and the drain electrode 38 is reduced, and hence the characteristics of the element deteriorates. Accordingly, from the viewpoint of the characteristics of the element, the channel length L (see FIG. 4) is preferably equal to or less than 10,000 μm.

The materials forming the gate electrode 30, the source electrode 36, and the drain electrode 38 are not particularly limited as long as all of the materials have high conductivity, and it is possible to use various known electrode-forming materials used in the thin film transistors of the related art.

Specifically, it is possible to use a metal such as Ag, Au, Al, Cu, Pt, Pd, Zn, Sn, Cr, Mo, Ta, or Ti, Al—Nd, and a metal oxide such as tin oxide, zinc oxide, indium oxide, indium tin oxide (ITO), or indium zinc oxide (IZO).

All of the gate electrode 30, the source electrode 36, and the drain electrode 38 can be formed by methods such as a printing method, a vacuum film-forming method, a plating method, and a laser patterning method. Furthermore, the electrodes can be formed by a method as a combination of a photolithography method and various film-forming methods. It is particularly preferable to form the electrodes by using a printing method.

The printing method includes various known printing methods such as an offset printing method, a gravure printing method, a reverse printing method, a flexographic printing method, a letterpress printing method, and a screen printing method. Among these, an offset printing method, a flexographic printing method, and a reverse printing method are preferable.

It is the characteristic of the printing method that patterns of electrodes can be formed on a substrate through a single step. The printing method may be combined with other methods. For example, a method of forming a substance to be a core of plating by a printing method and then forming a patterned electrode by plating or a method of performing printing on the whole surface of the substrate and then directly forming a pattern by using a laser or the like may be adopted.

In a case where the electrodes are formed by a printing method, by coating a substrate with a coating material (liquid viscous material), obtained by dispersing fine particles of the aforementioned material in a solvent, by a printing method according to a predetermined pattern and curing the coating material, the electrodes can be formed.

The solvent is not particularly limited, and it is possible to use various known solvents used in a case where the aforementioned material is used for printing.

The curing of the coating material is preferably photocuring or thermal curing. In a case where photocuring is adopted, it is preferable to cure the coating material by laser irradiation.

Considering film formability, patterning properties, conductivity, and the like, the thickness of the source electrode 36 and the drain electrode 38 is preferably 10 nm to 1,000 nm, and more preferably 50 nm to 200 nm.

Considering the film formability, patterning properties, conductivity, and the like, the thickness of the gate electrode 30 is preferably 10 nm to 1,000 nm, and more preferably 50 nm to 200 nm.

The gate electrode, the source electrode, and the drain electrode may be formed of different materials, but it is preferable that they are formed of the same material. By using the same material as the material forming the electrodes, the productivity can be improved.

In a case where the gate electrode, the source electrode, and the drain electrode are formed respectively, the input wiring 23 and 25 connected to each of these electrodes may be integrally formed.

In a case where the formation of the input wiring 23 and 25 connected to the electrodes is performed simultaneously with the formation of the electrodes, the number of steps can be reduced, and the productivity can be further improved.

In addition, in a case where the formation of each of the gate electrode, the source electrode, and the drain electrode is performed simultaneously with the formation of the input wiring 23 and 25, the positional accuracy of the gate electrode, the source electrode, the drain electrode, and the input wiring 23 and 25 can be further improved. As a result, the electric connection between the gate electrode, the source electrode, as well as the drain electrode and the input wiring 23 and 25 can be more reliably established, and hence the reliability can be improved. Furthermore, consequently, the yield becomes excellent, and the productivity can be improved.

In a case where the input wiring 23 and 25, the gate electrode, the source electrode, and the drain electrode are simultaneously formed, the material forming the input wiring 23 and 25 is preferably the same as the material of the gate electrode, the source electrode, and the drain electrode connected to the wiring.

The semiconductor layer 34 will be described. The constitution of the semiconductor layer 34 is not particularly limited, and the semiconductor layer 34 can be constituted with an organic semiconductor or an inorganic semiconductor, for example.

In a case where the semiconductor layer 34 is constituted with an organic semiconductor, the semiconductor layer can be easily prepared, bending properties thereof become excellent, and coating can be performed.

As the organic semiconductor constituting the semiconductor layer 34, for example, it is possible to use a pentacene derivative such as 6,13-bis(triisopropylsilylethynyl)pentacene (TIPS pentacene), an anthradithiophene derivative such as 5,11-bis(triethylsilylethynyl)anthradithiophene (TES-ADT), a benzodithiophene (BDT) derivative, a benzothienobenzothiophene (BTBT) derivative such as dioctylbenzothienobenzothiophene (C8-BTBT), a dinaphthothienothiophene (DNTT) derivative, a dinaphthobenzodithiophene (DNBDT) derivative, a 6,12-dioxaanthanthrene(perioxanthenoxanthene) derivative, a naphthalene tetracarboxylic acid diimide (NTCDI) derivative, a perylenetetracarboxylic acid diimide (PTCDI) derivative, a polythiophene derivative, a poly(2,5-bis(thiophen-2-yl)thieno[3,2-b]thiophene) (PBTTT) derivative, a tetracyanoquinodimethane (TCNQ) derivative, oligothiophenes, phthalocyanines, fullerenes, a polyacetylene-based conductive polymer, a polyphenylene-based conductive polymer such as polyparaphenylene and a derivative thereof and polyphenylene vinylene and a derivative thereof, polypyrrole and a derivative thereof, polythiophene and a derivative thereof, a heterocyclic conductive polymer such as polyfuran and a derivative thereof, and an ionic conductive polymer such as polyaniline and a derivative thereof.

Among the aforementioned organic semiconductors, the fullerenes, the naphthalene tetracarboxylic acid diimide (NTCDI) derivative, the perylenetetracarboxylic acid diimide (PTCDI) derivative, the tetracyanoquinodimethane (TCNQ) derivative described above are generally used in an N-type organic semiconductor layer, and other organic semiconductors are used in a P-type organic semiconductor layer. However, the aforementioned organic semiconductor can be a P-type or an N-type depending on the derivative.

In a case where the semiconductor layer 34 is constituted with an organic semiconductor, the method for forming the semiconductor layer 34 is not particularly limited, and it is possible to appropriately use known methods such as a coating method, a transfer method, and a vapor deposition method.

Considering the film formability and the like, the thickness of the semiconductor layer 34 is preferably 1 nm to 1,000 nm, and more preferably 10 nm to 300 nm.

As an inorganic semiconductor constituting the semiconductor layer 34, for example, it is possible to use silicon and an oxide semiconductor such as zinc oxide (ZnO) or In—Ga—ZnO₄.

In a case where the semiconductor layer 34 is constituted with an inorganic semiconductor, the method for forming the semiconductor layer 34 is not particularly limited, and it is possible to use a coating method and a vacuum film-forming method such as a vacuum vapor deposition method and a chemical vapor deposition method. For example, in a case where the semiconductor layer 34 is formed using silicon by a coating method, cyclopentasilane and the like can be used.

The insulating layer 32 is not particularly limited as long as it has high insulating properties, and it is possible to use various known insulating layer-forming materials used in thin film transistors of the related art.

Specifically, it is possible to use insulating compounds such as SiO₂, SiN_{X}, SiON, Al₂O₃, Y₂O₃, Ta₂O₅, and HfO₂. Furthermore, the insulating layer 32 may contain at least two or more compounds described above. From the viewpoint of high insulating properties, materials containing SiO₂ are preferably used.

The insulating layer 32 can be formed according to a method appropriately selected from wet methods such as a printing method and a coating method, physical methods such as a vacuum vapor deposition method, a sputtering method, and an ion plating method, chemical methods such as CVD and a plasma CVD method in consideration of the suitability with the material to be used. Furthermore, the insulating layer 32 may be formed in a preset shape by a photolithography method and etching.

The present invention is basically constituted as above. Hitherto, the electronic circuit device and the method for manufacturing an electronic circuit device of the present invention have been specifically described, but the present invention is not limited to the above embodiments. It goes without saying that within a scope that does not depart from the gist of the present invention, the present invention may be ameliorated or modified in various ways.

### EXPLANATION OF REFERENCES

10: input processing device
12: input portion
14: electronic circuit portion
16: output portion
18: power source portion
20, 20a to 20c: logic circuit element
21: electronic circuit
21a: input terminal
21b: ground terminal
22: P-type transistor
23, 25: input signal wiring (input wiring)
24: N-type transistor
26a: first input terminal
26b: second input terminal
26c: output terminal
27: output signal wiring (output wiring)
27a: wiring portion
27b: wiring portion
27c, 52: via
30: gate
32: insulating layer
34: semiconductor layer
36: source electrode
38: drain electrode
39: substrate
40, 46: connection wiring
42, 44a, 44b, 45a, 45b: intersection point
47: region in which connection wiring is supposed to be formed
50, 56: contact hole
52: via
54: metal layer
L: channel length
S10 to S18: step

What is claimed is:

1. An electronic circuit device comprising:
a plurality of logic circuit elements which are constituted with transistors and outputs an output signal by performing a preset operation on an input signal,
wherein the transistors each have a gate electrode provided on a substrate, an insulating layer electrically insulating the gate electrode, a source electrode, a drain electrode, and a semiconductor layer,
input signal wiring, to which the input signal is applied, is connected to the gate electrode and provided inside the insulating layer on the substrate,
output signal wiring, from which the output signal is taken out, is connected to the source electrode or the drain electrode and provided inside the insulating layer on the substrate, and
an electronic circuit performing a preset processing is constituted with the plurality of logic circuit elements.

2. The electronic circuit device according to claim 1,
wherein at least one connection wiring, which connects the input signal wiring of one of the logic circuit elements to the output signal wiring of another logic circuit elements is provided on the insulating layer such that the plurality of logic circuit elements are connected to each other.

3. The electronic circuit device according to claim 2,
wherein the connection wiring is electrically connected to the input signal wiring and the output signal wiring through a conductive member formed in the insulating layer.

4. The electronic circuit device according to claim 2,
wherein the input signal wiring and the output signal wiring are disposed in parallel to each other, and
the connection wiring is disposed crossing the input signal wiring and the output signal wiring.

5. The electronic circuit device according to claim 1,
wherein the semiconductor layer is constituted with an organic semiconductor or an inorganic semiconductor.

6. The electronic circuit device according to claim 1,
wherein each of the transistors is a combination of a P-type transistor and an N-type transistor.

7. The electronic circuit device according to claim 2,
wherein among the plurality of logic circuit elements, some logic circuit elements are selectively connected to each other by using the connection wiring.

8. A method for manufacturing an electronic circuit device which includes a plurality of logic circuit elements constituted with transistors and outputting an output signal by performing a preset operation on an input signal and in which an electronic circuit performing a preset processing is constituted with the plurality of logic circuit elements, the transistors each have a gate electrode provided on a substrate, an insulating layer electrically insulating the gate electrode, a source electrode, a drain electrode, and a semiconductor layer, input signal wiring, to which the input signal is applied, is connected to the gate electrode and provided inside the insulating layer on the substrate, output signal wiring, from which the output signal is taken out, is connected to the source electrode or the drain electrode and provided inside the insulating layer on the substrate, and at least one connection wiring crossing the plurality of logic circuit elements is provided on the insulating layer such that the plurality of logic circuit elements are connected to each other, the method comprising:
a step of selecting the logic circuit elements to be connected from the plurality of logic circuit elements;
a step of exposing the input signal wiring by forming a contact hole in the connection wiring and the insulating layer at an intersection point between the input signal wiring of the selected logic circuit elements and the connection wiring;
a step of exposing the output signal wiring by forming a contact hole in the connection wiring and the insulating layer at an intersection point between the output signal wiring of the logic circuit elements and the connection wiring; and
a step of electrically connecting the input signal wiring to the connection wiring and the output signal wiring to the connection wiring by filling each contact hole with a conductive member.

9. A method for manufacturing an electronic circuit device which includes a plurality of logic circuit elements constituted with transistors and outputting an output signal by performing a preset operation on an input signal and in which an electronic circuit performing a preset processing is constituted with the plurality of logic circuit elements, the transistors each have a gate electrode provided on a substrate, an insulating layer electrically insulating the gate electrode, a source electrode, a drain electrode, and a semiconductor layer, input signal wiring, to which the input signal is applied, is connected to the gate electrode and provided inside the insulating layer on the substrate, output signal wiring, from which the output signal is taken out, is connected to the source electrode or the drain electrode and provided inside the insulating layer on the substrate, the method comprising:
a step of selecting the logic circuit elements to be connected from the plurality of logic circuit elements;
a step of exposing the output signal wiring by forming a contact hole in the insulating layer on the output signal wiring of the selected logic circuit elements;
a step of exposing the input signal wiring by forming a contact hole in the insulating layer on the input signal wiring of the logic circuit elements into which the output signal of the selected logic circuit elements is input; and
a step of forming the connection wiring electrically connecting the input signal wiring to the output signal wiring by filling each contact hole with a conductive member.

10. The method for manufacturing an electronic circuit device according to claim 8,
wherein the input signal wiring and the output signal wiring are disposed in parallel to each other, and
the connection wiring is disposed crossing the input signal wiring and the output signal wiring.

11. The method for manufacturing an electronic circuit device according to claim 8,
wherein the step of selecting the logic circuit elements to be connected includes a step of selecting logic circuit elements which can perform a preset operation by inspecting the plurality of logic circuit elements and selecting logic circuit elements which will constitute the electronic circuit from the selected logic circuit elements.

12. The method for manufacturing an electronic circuit device according to claim 8,
wherein the semiconductor layer is constituted with an organic semiconductor or an inorganic semiconductor.

13. The method for manufacturing an electronic circuit device according to claim 8,
wherein each of the transistors is a combination of a P-type transistor and an N-type transistor.

14. The electronic circuit device according to claim 3,
wherein the input signal wiring and the output signal wiring are disposed in parallel to each other, and
the connection wiring is disposed crossing the input signal wiring and the output signal wiring.

15. The electronic circuit device according to claim 2,
wherein the semiconductor layer is constituted with an organic semiconductor or an inorganic semiconductor.

16. The electronic circuit device according to claim 2,
wherein each of the transistors is a combination of a P-type transistor and an N-type transistor.

17. The method for manufacturing an electronic circuit device according to claim 9,
wherein the input signal wiring and the output signal wiring are disposed in parallel to each other, and
the connection wiring is disposed crossing the input signal wiring and the output signal wiring.

18. The method for manufacturing an electronic circuit device according to claim 9,
wherein the step of selecting the logic circuit elements to be connected includes a step of selecting logic circuit elements which can perform a preset operation by inspecting the plurality of logic circuit elements and selecting logic circuit elements which will constitute the electronic circuit from the selected logic circuit elements.

19. The method for manufacturing an electronic circuit device according to claim 9,
wherein the semiconductor layer is constituted with an organic semiconductor or an inorganic semiconductor.

20. The method for manufacturing an electronic circuit device according to claim 9,
wherein each of the transistors is a combination of a P-type transistor and an N-type transistor.
